(19) United States
(12) Patent Application Publication
(10) Pub. No.: US 2014/0111077 A1
(43) Pub. Date: Apr. 24, 2014

(54) ELASTIC POSITIONING STRUCTURE FOR REMOVABLE HARD DRIVE

(71) Applicant: AIC INC., Taoyuan Hsien (TW)

(72) Inventor: Chung-I KUO, Taoyuan Hsien (TW)

(73) Assignee: AIC INC., Taoyuan Hsien (TW)

(21) Appl. No.: 13/782,806

(22) Filed: Mar. 1, 2013

Related U.S. Application Data
(63) Continuation-in-part of application No. 13/656,751, filed on Oct. 22, 2012.

(51) Int. Cl. H05K 7/18

(52) U.S. Cl. CPC H05K 7/183
USPC 312/333

(57) ABSTRACT

The positioning structure includes an enclosure, a tray and a hard drive box. The enclosure has a plurality of rails and a stopping hole. The tray includes a bottom and two side walls vertically extending therefrom. One of the side walls is formed with an elastic pillar, and the elastic arm has a tongue with a protrusion. The hard drive box is received in the tray and has a positioning hole corresponding to the protrusion. When the tray is being slid into the enclosure, the elastic arm engages the protrusion with the positioning hole. When the tray is being slid out of the enclosure, the elastic arm engages with the stopping hole.

### CROSS-REFERENCE TO RELATED APPLICATIONS

This application is a continuation-in-part of U.S. patent application Ser. No. 13/656,751, filed Oct. 22, 2012, now pending.

### BACKGROUND OF THE INVENTION

1. Technical Field

The invention relates to a fixture of data storage device, particularly to a fixture of removable hard drive rack.

2. Related Art

With popularization of computers, many kinds of peripheral devices appear in the markets to satisfy user's requirements, for example, a removable hard drive for data storage (installed in a removable hard drive rack). Because of the advantages of plug-and-play and capability for storage of a bulky amount of data, the removable hard drive has been widely adopted by users.

Such a removable hard drive rack can allow a hard drive to be directly detached from a computer case without disassembly. It is more convenient than conventional installation of hard drives.

However, current removable hard drive racks usually require a hand tool to fasten screws into a case. On the other hand, to remove the hard drive, the hand tool is still required. Because the screws are symmetrically fastened to two opposite sides of the removable hard drive rack, difficulty of positioning and asymmetry of fastening forces happens frequently. Moreover, the disassembled screws are hard to be kept and a hand tool is required when installing and disassembling, these will cause complication and inconvenience.

### SUMMARY OF THE INVENTION

An object of the invention is to provide an elastic positioning structure for a removable hard drive which has an advantage of easy installation and positioning.

Another object of the invention is to provide an elastic positioning structure for a removable hard drive which does not require any hand tool when installing and positioning and can avoid loss of screws.

To achieve the above objects, the positioning structure of the invention includes an enclosure, a tray and a hard drive box. The enclosure has a plurality of rails and a stopping hole. The tray includes a bottom and two side walls vertically extending therefrom. One of the side walls is formed with an elastic pillar, and the elastic arm has a tongue with a protrusion. The hard drive box is received in the tray and has a positioning hole corresponding to the protrusion. When the tray is being slid into the enclosure, the elastic arm engages the protrusion with the positioning hole. When the tray is being slid out of the enclosure, the elastic arm engages with the stopping hole.

### BRIEF DESCRIPTION OF THE DRAWINGS

FIG. 1 is a perspective view of the invention;

FIG. 2 is an assembled view of the removable hard drive of the invention;

FIG. 3 is an exploded view of the removable hard drive of the invention;

FIG. 4 is a sectional view of the invention which shows the removable hard drive is fastened to the enclosure;

FIG. 5 is another sectional view of the invention which shows the removable hard drive is fastened to the enclosure;

FIG. 6 is a schematic view which shows the removable hard drive is drawn out; and

FIG. 7 is a schematic view shows multiple enclosures are combined.

### DETAILED DESCRIPTION OF THE INVENTION

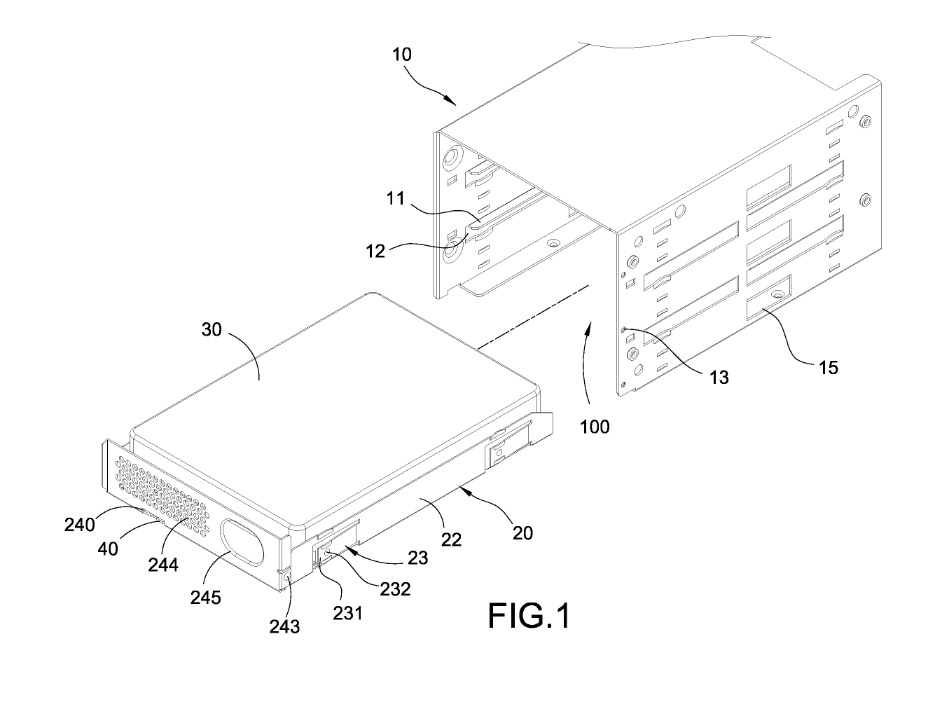

Please refer to FIGS. 1-3. The invention includes an enclosure 10, a tray 20 and a hard drive box 30. A removable hard drive is composed of the tray 20 and the hard drive box 30. The hard drive 30 accommodating a hard drive (not shown) is fixed in the tray 20 and the tray 20 is slidably positioned in the enclosure 10.

The enclosure 10 is a metal frame with a receiving room 100 and is provided with a plurality of rails 11 and a stopping hole 15. The rails 11 are formed by a pressing process. A slot 12 is formed near each of the rails 11.

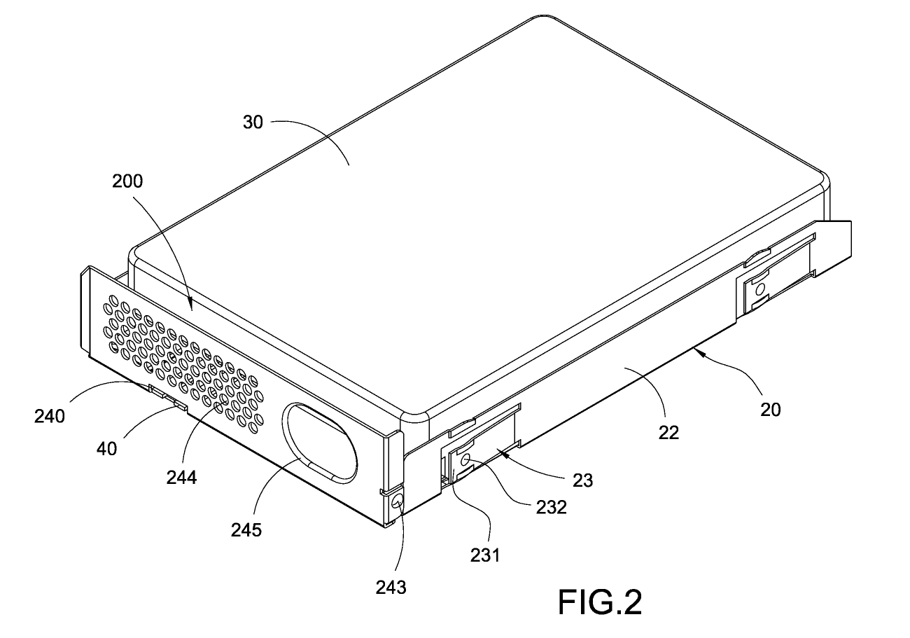

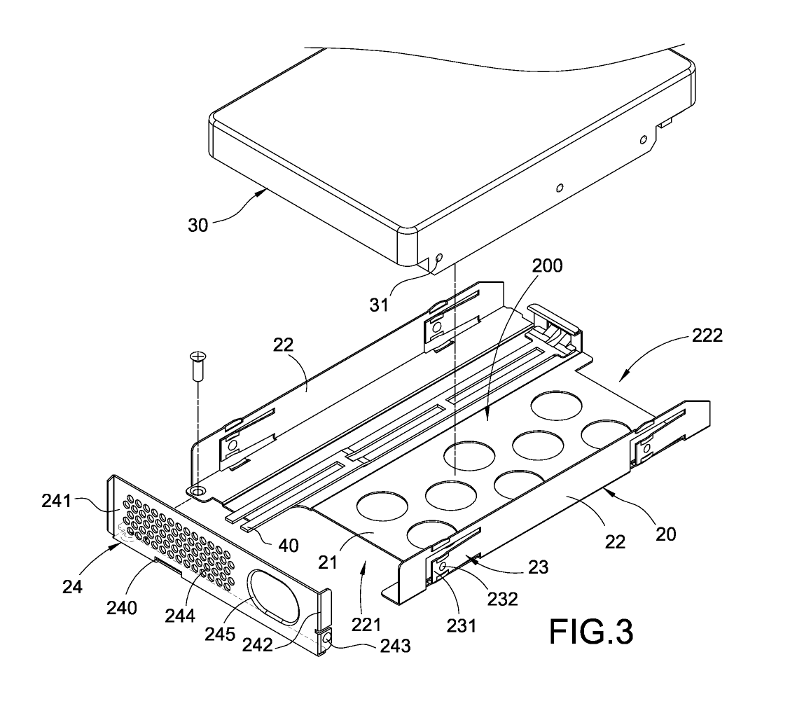

Please refer to FIGS. 2 and 3. The tray 20 includes a bottom 21 and two side walls 22 perpendicularly extending therefrom. A space 200 is formed between the bottom 21 and side walls 22. The tray 20 can be inserted into the receiving room 100. One of the side walls 22 is provided with an elastic arm 23. The elastic arm 23 is formed with a tongue 231 with a protrusion 232. Multiple elastic arms 23 are available and may be horizontally arranged in the side walls 22.

A front opening 221 and a rear opening 222 are formed between the two side walls 22. The tray 20 further includes a rotatable cover 24 connected to the bottom 21 to cloak the front opening 221. The rotatable cover 24 has a pivot end 241 rotatably connected to the bottom 21 and a free end 242 which can be selectively locked onto the enclosure 10.

Preferably, the rotatable cover 24 is further formed with a button 243 and the enclosure 10 is correspondingly formed with a recess 13. The rotatable cover 24 may be locked onto the enclosure 10 by the engagement of the button 243 and the recess 13. Additionally, the rotatable cover 24 may be further provided with vents 244 and a finger hole 245 for being easy to open the rotatable cover 24 with a finger of a user.

The hard drive box 30 is received in the tray 20. One side of the hard drive box 30 is formed with a positioning hole 31 corresponding to the protrusion 232.

The tray 20 may be preferably provided with a light guide member 40 and a light source (not shown). The light guide member 40 is exposed in the rotatable cover 24. In the shown embodiment, the bottom of the rotatable cover 24 is formed with a groove 240 to receive the light guide member 40.

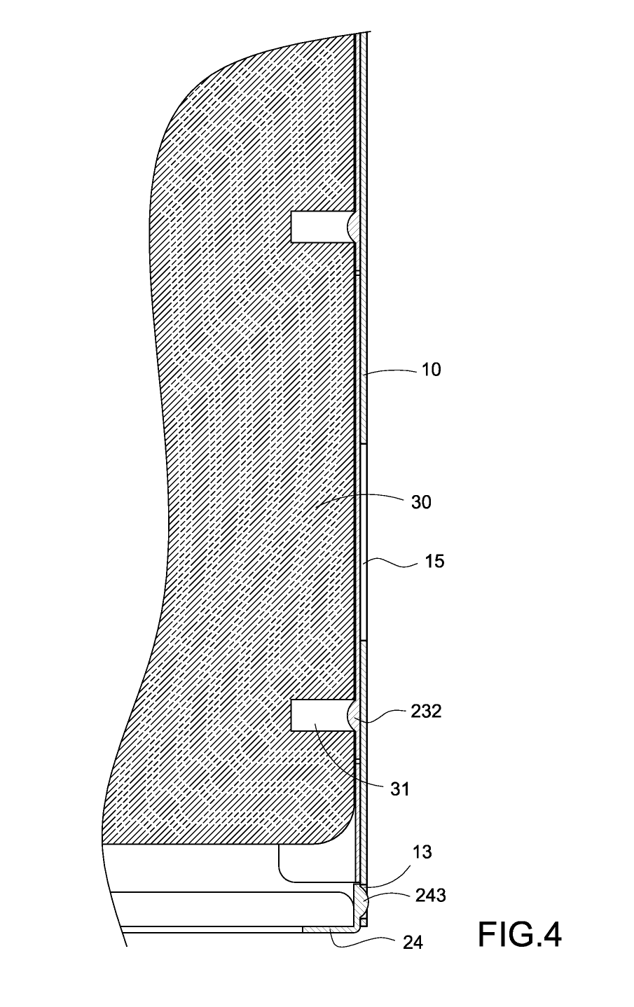

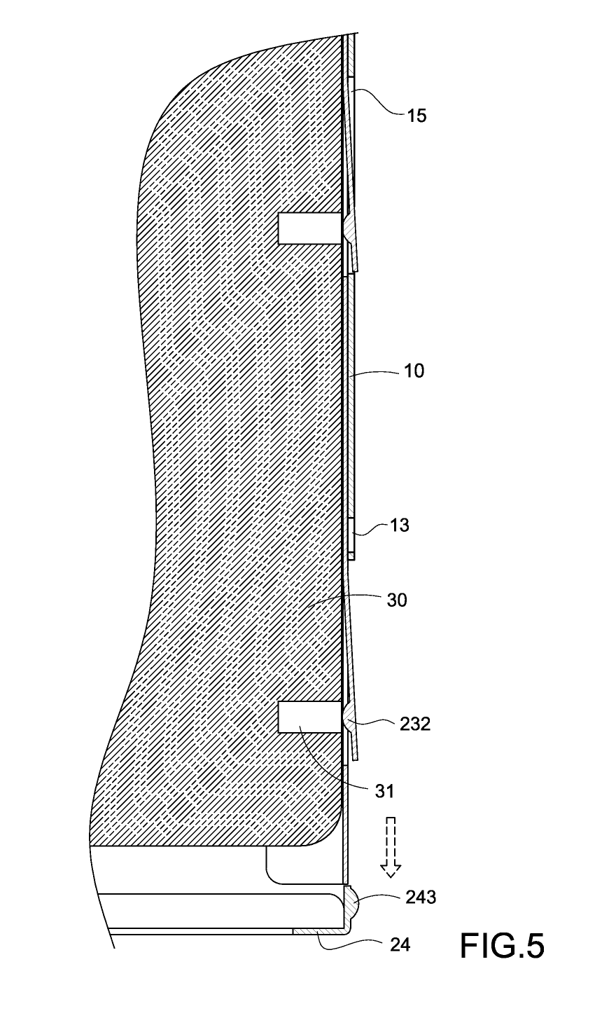

Please refer to FIGS. 4 and 5. As shown, a hard drive can be fastened to the enclosure 10 through the hard drive box 20.

When using, the hard drive box 20 is slid into the receiving room 100 along the rails 11. The elastic arm 23 is pressed by the enclosure 10 to deform inward and the protrusion 232 is engaged to the positioning hole 31. At this time, the tray 20 is further pushed until the button 243 is engaged to the recess 13. As a result, the free end 242 of the rotatable cover 24 is locked on the enclosure 10, i.e., the tray 20 is fixed in the enclosure 10. On the other hand, when the tray 20 is being slid out of the receiving room 100, the elastic arm 23 will protrude from and engages with the stopping hole 15.

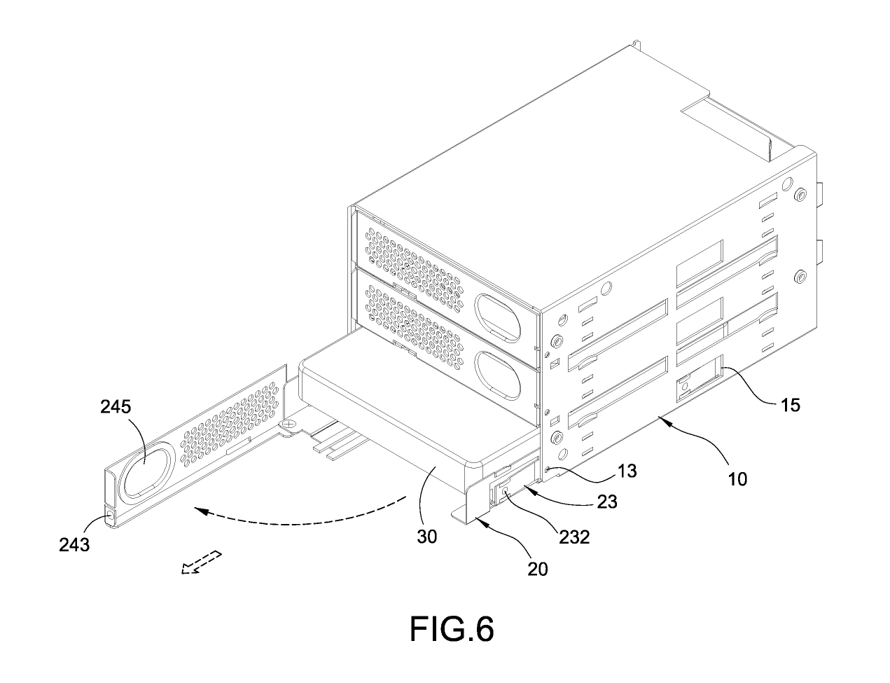

Please refer to FIG. 6. When a user intends to draw out from the enclosure 10, he or she can insert his or her finger into the finger hole 245 to draw the tray 20. Moreover, the hard drive 30 can be directly taken from the hard drive box 20 even if the tray 20 has not completely escaped from the enclosure 10.

When the tray 20 is pulled out, the button 243 will escape from the recess 13. Thus, the tray 20 can be removed from the enclosure 10. Meanwhile, the elastic arm 23 will also be released from the enclosure 10. Due to the elasticity of the elastic arm 23, the protrusion 232 will protrude from the positioning hole 31 to release the hard drive box 30 from the tray 20 (as shown in FIG. 4). Thus, the hard drive box 30 can be removed from the tray 20.

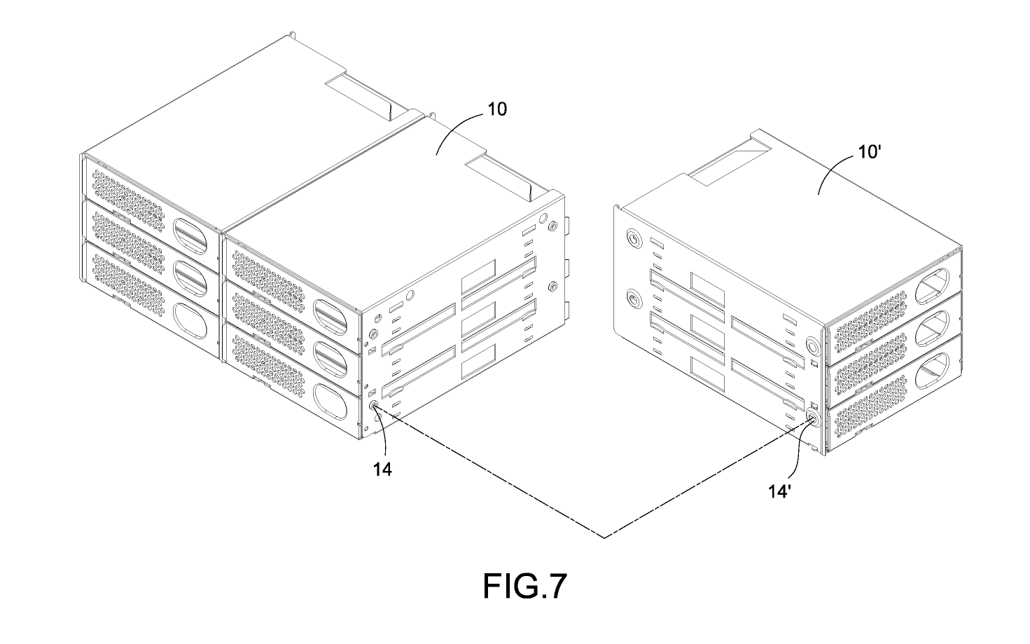

Please refer to FIG. 7. Outer sides of the enclosures 10, 10′ are provided with a pair of connecting portions 14, 14′. Two enclosures 10, 10′ can be combined by the connecting portions 14, 14′.

While the forgoing is directed to a preferred embodiment of the present invention, other and further embodiments of the invention may be devised without departing from the basic scope thereof. As such, the appropriate scope of the invention is to be determined according to the claims.

What is claimed is:

1. A positioning structure for a removable hard drive, comprising:
an enclosure, being a frame with a receiving room, and having a plurality of rails and a stopping hole;
a tray, including a bottom and two side walls vertically extending therefrom, a space being formed by the bottom and the side walls, one of the side walls being formed with an elastic pillar, and the elastic arm having a tongue with a protrusion; and
a hard drive box, received in the space, and having a positioning hole corresponding to the protrusion;
wherein when the tray is being slid into the receiving room along the rails, the elastic arm is pressed by the enclosure to engage the protrusion with the positioning hole; and when the tray is being slid out of the receiving room, the elastic arm protrudes from and engages with the stopping hole.

2. The positioning structure of claim 1, wherein a slot is formed near each of the rails.

3. The positioning structure of claim 1, wherein a front opening and a rear opening are formed between the two side walls, the tray further includes a rotatable cover connected to the bottom to cloak the front opening.

4. The positioning structure of claim 3, wherein the rotatable cover has a pivot end rotatably connected to the bottom and a free end which is selectively locked onto the enclosure.

5. The positioning structure of claim 4, wherein the rotatable cover is further formed with a button, and the enclosure is formed with a recess so that the rotatable cover may be locked onto the enclosure by the engagement of the button and the recess.

6. The positioning structure of claim 5, wherein the rotatable cover is further provided with vents and a finger hole 245 for being easy to open the rotatable cover 24 with a finger of a user.

7. The positioning structure of claim 1, wherein the tray has a plurality of elastic arms which are horizontally arranged in one of the side walls.

8. The positioning structure of claim 1, wherein an outer side of the enclosure is provided with a connecting portion to connect another enclosure.

9. The positioning structure of claim 3, wherein the tray is provided with a light guide member exposed in the rotatable cover.

10. The positioning structure of claim 9, wherein a bottom of the rotatable cover is formed with a groove to receive the light guide member.
